(19) United States
(12) Patent Application Publication
(10) Pub. No.: US 2017/0257075 A1
(43) Pub. Date: Sep. 7, 2017

(54) BAW DEVICE AND BAW DEVICE MANUFACTURING METHOD

(71) Applicant: DISCO CORPORATION, Tokyo (JP)

(72) Inventor: Jun Abatake, Tokyo (JP)

(21) Appl. No.: 15/447,534

(22) Filed: Mar. 2, 2017

(30) Foreign Application Priority Data
Mar. 3, 2016 (JP) 2016-041026

(51) Int. Cl. H03H 9/17; H03H 9/54; H03H 3/02

(52) U.S. Cl. CPC H03H 9/17; H03H 3/02; H03H 9/54

(57) ABSTRACT

A BAW device including a substrate, and a piezoelectric element formed on a front surface of the substrate is provided. The substrate is provided on a back surface side thereof with an acoustic wave diffusion region including a recess formed by partially melting a back surface of the substrate.

### BACKGROUND OF THE INVENTION

Field of the Invention

The present invention relates to a bulk acoustic wave (BAW) device utilizing a BAW propagated through the inside of a material, and a manufacturing method thereof.

Description of the Related Art

In telecommunication apparatuses such as a mobile phones, bandpass filters permitting electrical signals in a desired frequency band to pass therethrough play an important role. As one of the bandpass filters, there has been known a surface acoustic wave (SAW) device (SAW filter) utilizing a SAW. A SAW device includes a crystalline substrate including a piezoelectric material such as quartz (SiO₂), and a comb-shaped electrode (inter digital transducer (IDT)) formed on a surface of the crystalline substrate, and permits passage therethrough of only electrical signals in a frequency band which is determined according to the kind of the piezoelectric material, the interval of the electrodes, etc.

Meanwhile, in the SAW device, part of the acoustic wave (elastic wave) generated in the vicinity of an input-side electrode may be propagated through the inside of the crystalline substrate and reflected on the back surface side. If the reflected acoustic wave reaches an output-side electrode, the frequency characteristic of the SAW device would be deteriorated. In view of this, a finely rugged (projected and recessed) structure is formed on the back surface of the crystalline substrate so that the acoustic wave is scattered easily, whereby the arrival of the reflected acoustic wave at the electrode is prevented (for example, refer to Japanese Patent Laid-Open No. 2003-8396).

### SUMMARY OF THE INVENTION

In recent years, as an advanced form of SAW devices, BAW devices (BAW filters) utilizing a BAW propagated through the inside of a material have been drawing attention. A BAW device includes a resonator (piezoelectric element) wherein a piezoelectric film including a piezoelectric material such as aluminum nitride (AlN) is sandwiched between electrodes including molybdenum (Mo) or the like. The resonator is formed on a substrate including a semiconductor material such as silicon (Si). Unlike the SAW device, the BAW device does not have a comb-shaped electrode structure and, therefore, is advantageous from the viewpoint of lesser loss and higher power resistance. In addition, since the BAW device does not need to use a crystalline substrate including a piezoelectric material, it can be formed integrally with other active devices.

At the time of manufacturing a BAW device, for example, the back surface of a substrate formed on the front surface side thereof with a plurality of resonators is ground to thin the substrate to a predetermined thickness, after which dicing is conducted to divide the substrate into a plurality of BAW devices corresponding individually to the resonators. In the case of the BAW device, also, the frequency characteristic is deteriorated by acoustic waves reflected on the back surface side of the substrate. Therefore, in the above-mentioned step, rough grinding is conducted to form a finely rugged (projected and recessed) structure, and the resulting mechanical strains are removed by etching. However, when etching is adopted for removing the mechanical strains generated by the grinding, burden on environments is increased.

Accordingly, it is an object of the present invention to provide a BAW device and a BAW device manufacturing method wherein burden on environments at the time of manufacturing the BAW device is suppressed.

In accordance with an aspect of the present invention, there is provided a BAW device including a substrate, and a piezoelectric element formed on a front surface of the substrate, wherein the substrate is provided on a back surface side thereof with an acoustic wave diffusion region including a recess formed by partially melting a back surface of the substrate.

Besides, in accordance with another aspect of the present invention, there is provided a BAW device manufacturing method for manufacturing a BAW device. The BAW device includes a substrate, and a piezoelectric element formed on a front surface of the substrate. The substrate is provided on a back surface side thereof with an acoustic wave diffusion region including a recess formed by partially melting a back surface of the substrate. The BAW device manufacturing method includes a substrate preparation step of preparing the substrate formed on the front surface thereof with the piezoelectric element, and an acoustic wave diffusion region forming step of applying a laser beam having such a wavelength as to be absorbed in the substrate from the back surface side of the substrate, to partially melt the back surface of the substrate, thereby forming an acoustic wave diffusion region including a recess.

The BAW device according to the aspect of the present invention is provided with the acoustic wave diffusion region including the recess formed by partially melting the back surface of the substrate, and, therefore, does not need the formation of a finely rugged structure by rough grinding of the back surface of the substrate, which is needed in the cases of conventional BAW devices. Accordingly, it is unnecessary to adopt etching for removal of mechanical strains which would arise from grinding. Thus, burden on environments at the time of manufacturing the BAW device can be suppressed.

The above and other objects, features and advantages of the present invention and the manner of realizing them will become more apparent, and the invention itself will best be understood from a study of the following description and appended claims with reference to the attached drawings showing a preferred embodiment of the invention.

### BRIEF DESCRIPTION OF THE DRAWINGS

FIG. 1A is a perspective view showing schematically an upper-side external appearance of a BAW device;

FIG. 1B is a perspective view showing schematically a lower-side external appearance of the BAW device;

FIG. 1C is a sectional view showing schematically a stack structure of the BAW device;

FIG. 2A is a perspective view showing schematically a configuration example of a substrate formed with a plurality of resonance units;

FIG. 2B is a sectional view showing schematically the configuration example of the substrate formed with the plurality of resonance units;

FIG. 3 is a perspective view showing schematically a configuration example of a laser processing apparatus;

FIG. 4A is a partially sectional side view showing schematically an acoustic wave diffusion region forming step;

FIG. 4B is a partially sectional side view showing schematically a modified layer forming step; and

FIGS. 5A and 5B are partially sectional side views showing schematically a dividing step.

### DETAILED DESCRIPTION OF THE PREFERRED EMBODIMENT

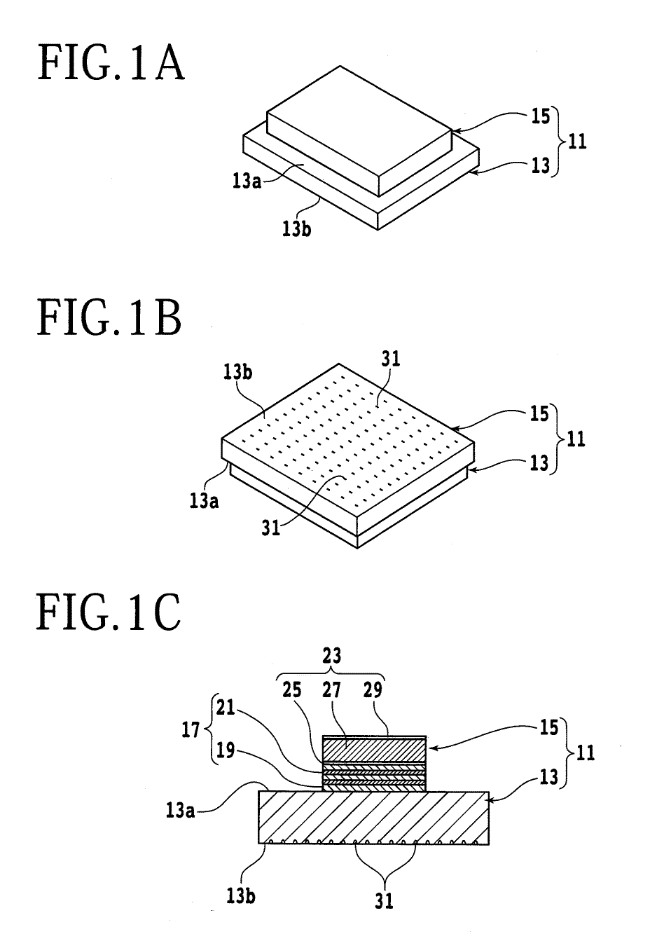

An embodiment of the present invention will be described below referring to the attached drawings. FIG. 1A is a perspective view showing schematically an upper-side external appearance of a BAW device; FIG. 1B is a perspective view showing schematically a lower-side external appearance of the BAW device; and FIG. 10 is a sectional view showing schematically a stack structure of the BAW device.

As illustrated in FIGS. 1A, 1B, and 1C, a BAW device (BAW device chip) 11 according to the present embodiment includes a rectangular substrate 13 including a semiconductor material such as crystalline silicon (Si). On a first surface (front surface) 13a of the substrate 13, there is provided a resonance unit 15 wherein films having various functions are stacked. The resonance unit 15 includes an acoustic multilayer film 17 formed on the lower side (the substrate 13 side). The acoustic multilayer film 17 is formed by stacking on each other a first film 19 including a material having a low acoustic impedance, such as silicon oxide (SiO₂), and a second film 21 including a material having a high acoustic impedance, such as tungsten (W). A resonator (piezoelectric element) 23 is provided on the upper side (on the side opposite to the substrate 13) of the acoustic multilayer film 17. The resonator 23 includes a lower electrode 25 including a conductive material such as molybdenum (Mo), a piezoelectric film 27 formed on the upper surface of the lower electrode 25 and including a piezoelectric material such as aluminum nitride (AlN), and an upper electrode 29 formed on the upper surface of the piezoelectric film 27 and including a conductive material such as molybdenum. The resonator 23 resonates a bulk acoustic wave, which is generated by the piezoelectric film 27, at a center frequency determined by the materials and thicknesses of the lower electrode 25, the piezoelectric film 27, and the upper electrode 29, and so on. The first film 19 and the second film 21 constituting the acoustic multilayer film 17 are formed in thicknesses equal to ¼ times the wavelengths in the films of the bulk acoustic wave resonated at the above-mentioned center frequency, and reflect the bulk acoustic wave resonated by the resonator 23 in such a condition that the bulk acoustic waves intensify each other. Consequently, the bulk acoustic wave generated by the resonator 23 can be prevented from being propagated to the substrate 13.

However, even in the case of the BAW device 11 configured as above, the bulk acoustic wave generated from the piezoelectric film 27 may slightly leak out to the substrate 13 side. If the bulk acoustic wave thus leaking out is reflected by a second surface (back surface) 13b or the like to re-enter the resonator 23, the frequency characteristic of the BAW device 11 would be deteriorated. In view of this, in the BAW device 11 according to the present embodiment, a plurality of acoustic wave diffusion regions 31 for diffusing (scattering) the bulk acoustic wave are provided in the second surface 13b of the substrate 13. The acoustic wave diffusion region 31 includes a recess formed by partially melting and removing the second surface 13b of the substrate 13 by a laser beam. The surrounding region of the recess is modified (for example, turned to be amorphous) through melting and re-solidification. Therefore, the propagation characteristic of the bulk acoustic wave propagated through the inside of the substrate 13 is varied in the surrounding regions of the recesses. In other words, the propagation direction of the bulk acoustic wave is also changed in the surrounding regions of the recesses. Note that the bulk acoustic wave having reached the recesses is diffused (scattered) at the recesses. Conditions such as the size and pitches of the recesses constituting the acoustic wave diffusion regions 31 can be arbitrarily adjusted within such ranges as to enable appropriate diffusion of the bulk acoustic wave. Note that in the present embodiment, the recesses having a size (width) of 7 to 8 μm are formed at pitches of 11 μm×15 μm. By forming such recesses in the second surface 13b of the substrate 13, the bulk acoustic wave propagated through the inside of the substrate 13 can be diffused and can be restrained from entering the resonator 23. In the present embodiment, therefore, it is unnecessary to roughly grind the back surface of the substrate to form a finely rugged (projected and recessed) structure for diffusion of the bulk acoustic wave. In other words, it is also unnecessary to etch the substrate 13 in order to remove mechanical strains arising from the grinding, so that burden on environments at the time of manufacture can be suppressed to a low level. Note that the acoustic wave diffusion regions 31 can not only diffuse the bulk acoustic wave leaking out from the piezoelectric film 27 but also diffuse noise components such as bulk acoustic waves generated for other reasons. Consequently, in the BAW device 11 according to the present embodiment, superior frequency characteristic can be realized as compared to conventional BAW devices.

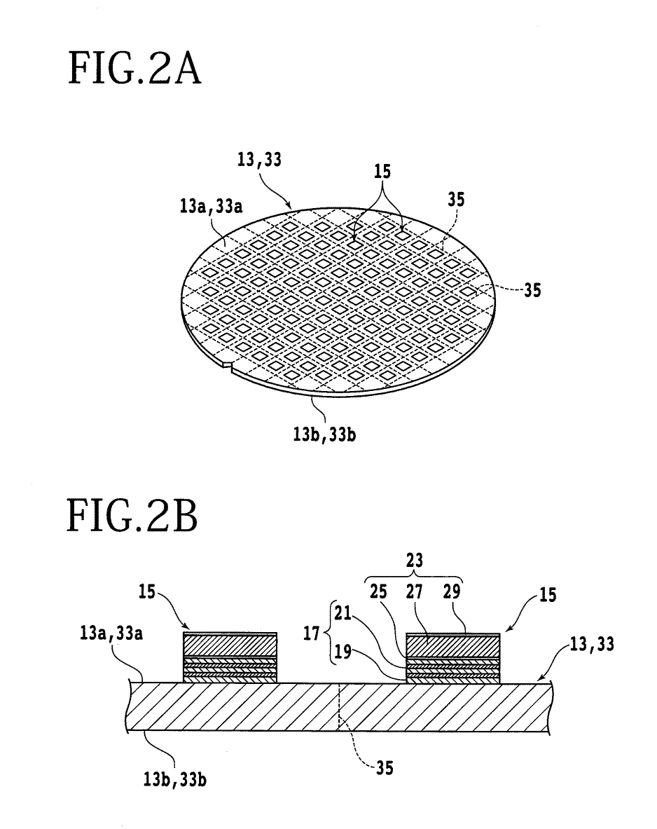

A BAW device manufacturing method for manufacturing the BAW device 11 described above will be described below. First, a substrate preparation step of preparing a substrate formed with a plurality of resonance units 15 (resonators 23) is conducted. FIG. 2A is a perspective view showing schematically a configuration example of the substrate formed with the plurality of resonance units 15, and FIG. 2B is a sectional view showing schematically the configuration example of the substrate formed with the plurality of resonance units 15. A substrate 33 is a circular wafer including a semiconductor material such as silicon, for example. A first surface (front surface) 33a of the substrate 33 is partitioned into a plurality of regions by crossing division lines (streets) 35, and the aforementioned resonance units 15 are provided in the regions. With the substrate 33 divided along the division lines 35, the BAW devices 11 each including a rectangular substrate 13 can be manufactured. Note that conditions such as the material and thickness of the substrate 33 can be arbitrarily varied within such ranges as to permit appropriate formation of acoustic wave diffusion regions 31. For example, the substrate 33 including ceramic such as alumina (Al₂O₃) may be used.

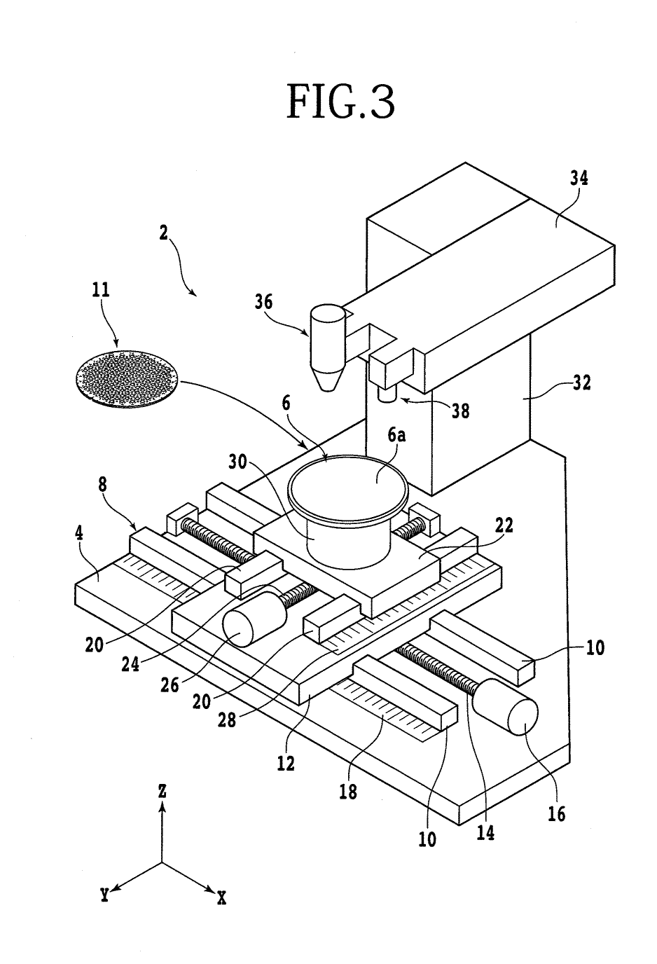

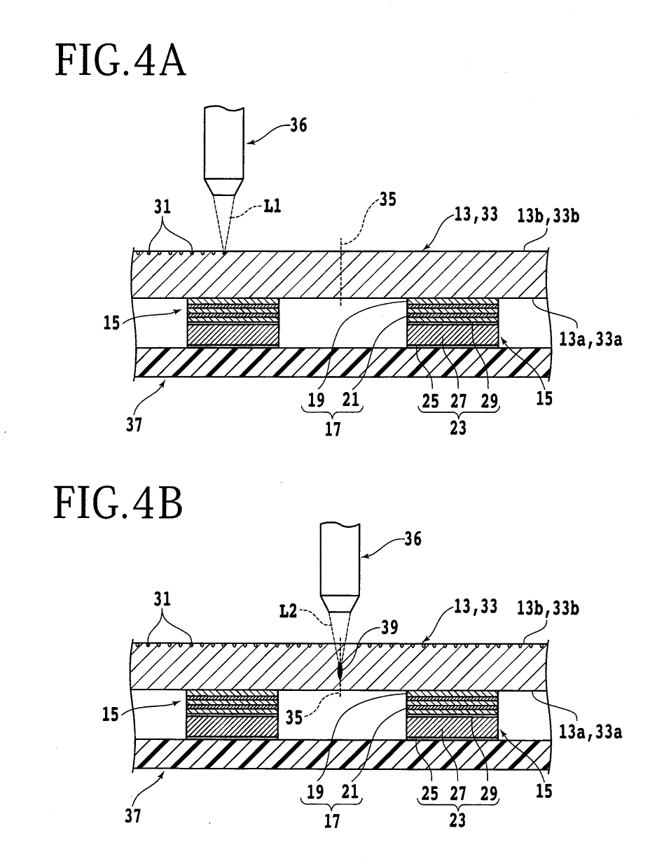

After the substrate preparation step of preparing the substrate 33 mentioned above is performed, an acoustic wave diffusion region forming step of forming the acoustic wave diffusion regions 31 in the substrate 33 is carried out. FIG. 3 is a perspective view showing schematically a configuration example of a laser processing apparatus to be used in the acoustic wave diffusion region forming step or the like, and FIG. 4A is a partially sectional side view showing schematically the acoustic wave diffusion region forming step. As illustrated in FIG. 3, a laser processing apparatus 2 includes a base 4 on which to mount each structure. On an upper surface of the base 4 is provided a horizontal movement mechanism 8 by which a chuck table 6 holding the substrate 33 thereon by suction is moved in an X-axis direction (processing feed direction) and a Y-axis direction (indexing feed direction). The horizontal movement mechanism 8 includes a pair of X-axis guide rails 10 which are fixed on the upper surface of the base 4 and are substantially parallel to the X-axis direction. An X-axis movement table 12 is slidably mounted to the X-axis guide rails 10. On a back surface side (lower surface side) of the X-axis movement table 12 is provided a nut section (not shown), which is in screw engagement with an X-axis ball screw 14 substantially parallel to the X-axis guide rails 10. To one end portion of the X-axis ball screw 14 is connected an X-axis pulse motor 16. With the X-axis ball screw 14 rotated by the X-axis pulse motor 16, the X-axis movement table 12 is moved in the X-axis direction along the X-axis guide rails 10. An X-axis scale 18 for detection of the position of the X-axis movement table 12 is arranged at a position adjacent to the X-axis guide rails 10. On a front surface (upper surface) of the X-axis movement table 12 is fixed a pair of Y-axis guide rails 20 which are substantially parallel to the Y-axis direction. A Y-axis movement table 22 is slidably mounted to the Y-axis guide rails 20. On a back surface side (lower surface side) of the Y-axis movement table 22 is provided a nut section (not shown), which is in screw engagement with a Y-axis ball screw 24 substantially parallel to the Y-axis guide rails 20. To one end portion of the Y-axis ball screw 24 is connected a Y-axis pulse motor 26. With the Y-axis ball screw 24 rotated by the Y-axis pulse motor 26, the Y-axis movement table 22 is moved in the Y-axis direction along the Y-axis guide rails 20. A Y-axis scale 28 for detection of the position of the Y-axis movement table 22 is arranged at a position adjacent to the Y-axis guide rails 20.

A support base 30 is provided on a front surface side (upper surface side) of the Y-axis movement table 22, and the chuck table 6 is disposed at an upper portion of the support base 30. A front surface (upper surface) of the chuck table 6 is a holding surface 6a for holding the aforementioned substrate 33 by suction. The holding surface 6a is connected to a suction source (not shown) through a suction passage (not shown), which is formed in the inside of the chuck table 6, and the like. On the lower side of the chuck table 6 is provided a rotational drive source (not shown), and the chuck table 6 is rotated about a rotational axis substantially parallel to a Z-axis direction by the rotational drive source. A columnar support structure 32 is provided on a rear side of the horizontal movement mechanism 8. A support arm 34 extending in the Y-axis direction is fixed to an upper portion of the support structure 32, and a laser application unit 36 for applying a pulse-oscillated laser beam to the substrate 33 on the chuck table 6 is provided at a tip end portion of the support arm 34. A camera 38 for imaging the substrate 33 is provided at a position adjacent to the laser application unit 36. An image formed by imaging the substrate 33 and the like by the camera 38 is used, for example, for adjusting the positions of the substrate 33 and the laser application unit 36, or the like. The components such as the chuck table 6, the horizontal movement mechanism 8, the laser application unit 36, and the camera 38 are connected to a control unit (not shown). The control unit controls operations of the components in such a manner that the substrate 33 is processed suitably.

In the acoustic wave diffusion region forming step, first, a protective tape 37 is adhered to the first surface 33a side (the resonance unit 15 side) of the substrate 33, as illustrated in FIG. 4A. Next, the substrate 33 is placed on the chuck table 6 in such a manner that the protective tape 37 and the holding surface 6a face each other, and a negative pressure of the suction source is applied to the holding surface 6a. By this, the substrate 33 is suction held on the chuck table 6 in a state where the second surface 33b side is exposed to the upper side. Subsequently, the chuck table 6 is moved and rotated, to adjust the laser application unit 36 to a starting position at which to start formation of the acoustic wave diffusion regions 31. Then, as shown in FIG. 4A, while a laser beam L1 having such a wavelength as to be easily absorbed in the substrate 33 is applied from the laser application unit 36 toward the substrate 33, the chuck table 6 is moved in a horizontal direction. Here, a focal point of the laser beam L1 is positioned to a position in the vicinity of the second surface 33b of the substrate 33. Thus, the laser beam L1 having such a wavelength as to be easily absorbed in the substrate 33 is applied in the state of being focused on a point in the vicinity of the second surface 33b from the second surface 33b side of the substrate 33, whereby the second surface 33b side of the substrate 33 can be partially melted and removed, to form a recess that constitutes the acoustic wave diffusion region 31. The surrounding region of the recess formed by such a method (ablation processing) is modified (for example, turned to be amorphous) through melting and re-solidification. Therefore, propagation characteristic of a bulk acoustic wave propagated through the substrate 13 is changed in the surrounding region of the recess. In other words, the propagation direction of the bulk acoustic wave is also changed in the surrounding region of the recess. Thus, the bulk acoustic wave is suitably diffused (scattered) by the recess and its surrounding region.

For example, in the case where recesses having a size (width) of 7 to 8 μm are to be formed at pitches of 11×15 μm in the substrate 33 including silicon, the processing conditions are set as follows.

Wavelength: 532 nm (YVO₄ pulsed laser)

Repetition frequency: 200 kHz

Output: 0.2 W

Under such conditions, the recesses constituting the acoustic wave diffusion regions 31 are formed over substantially the whole body of the substrate 33 exclusive of portions in the vicinity of the division lines 35, whereon the acoustic wave diffusion region forming step is finished. Note that the processing conditions are not limited to the above-mentioned, and can be arbitrarily changed according to the size and pitches of the recesses constituting the acoustic wave diffusion regions 31, and the like.

After the acoustic wave diffusion region forming step, a modified layer forming step of forming modified layers to be starting points for division along the division lines 35 of the substrate 33 is carried out. FIG. 4B is a partially sectional side view showing schematically the modified layer forming step. The modified layer forming step can be performed by use of the same laser processing apparatus 2 as in the acoustic wave diffusion region forming step. It is to be noted here, however, that in the modified layer forming step a laser beam having such a wavelength as to be difficultly absorbed in (be transmitted through) the substrate 33 should be applied from the laser application unit 36. Specifically, first, the chuck table is moved and rotated, to adjust the laser application unit 36 to an end portion of the division line 35 serving as a target of processing. Then, as shown in FIG. 4B, while a laser beam L2 having such a wavelength as to be difficultly absorbed in (be transmitted through) the substrate 33 is applied from the laser application unit 36 toward the substrate 33, the chuck table 6 is moved in a direction parallel to the division line 35 serving as the target of processing. Specifically, the laser beam L2 having such a wavelength as to be difficultly absorbed in the substrate 33 is applied along the division line 35 from the second surface 33b side of the substrate 33. Here, the position of the focal point of the laser beam L2 is preliminarily adjusted to a point in the inside of the substrate 33. By this, the inside of the substrate 33 can be modified (altered) along the division line 35, thereby forming a modified layer 39.

For example, in the case of forming the modified layer 39 in the substrate 33 including silicon, the processing conditions are set as follows.

Wavelength: 1064 nm (YVO₄ pulsed laser)

Repetition frequency: 100 kHz

Output: 1 to 1.5 W

Moving speed (Processing feed speed): 100 mm/s

Note that such conditions as power density of the laser beam L2 are adjusted within such ranges as to permit formation of a suitable modified layer 39 in the inside of the substrate 33. This procedure is repeated to form the modified layers 39 along all the division lines 35, whereon the modified layer forming step is finished.

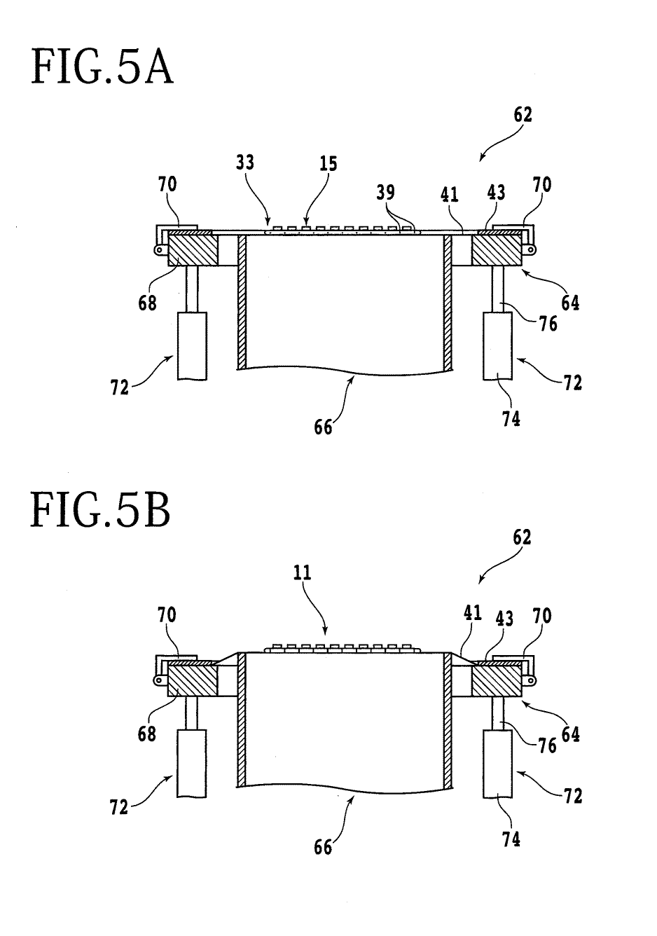

After the modified layer forming step, a dividing step of applying an external force to the substrate 33 to divide the substrate 33 along the division lines 35 into a plurality of substrates 13 (BAW devices 11) is carried out. FIGS. 5A and 5B are partially sectional side views showing schematically the dividing step. In the dividing step, first, an expansion tape 41 is attached to the second surface 33b of the substrate 33, and an annular frame 43 is fixed to an outer peripheral portion of the expansion tape 41. In addition, the protective tape 37 having been adhered to the first surface 33a side of the substrate 33 is peeled and removed.

As illustrated in FIGS. 5A and 5B, an expanding apparatus 62 includes a support structure 64 for supporting the substrate 33, and a hollow cylindrical expansion drum 66 for expanding the expansion tape 41 attached to the substrate 33. The inside diameter of the expansion drum 66 is greater than the diameter of the substrate 33, and the outside diameter of the expansion drum 66 is smaller than the inside diameter of the frame 43. The support structure 64 includes a frame support table 68 for supporting the frame 43. An upper surface of the frame support table 68 is a support surface for supporting the frame 43. The frame support table 68 is provided at an outer peripheral portion thereof with a plurality of clamps 70 for fixing the frame 43. A lift mechanism 72 is provided on the lower side of the support structure 64. The lift mechanism 72 includes cylinder cases 74 fixed on a base (not shown) on the lower side, and piston rods 76 inserted in the cylinder cases 74. The frame support table 68 is fixed to upper end portions of the piston rods 76. The lift mechanism 72 lifts the support structure 64 upward and downward in such a manner that the upper surface (support surface) of the frame support table 68 is moved between a reference position equal in height to the upper end of the expansion drum 66 and an expansion position below the upper end of the expansion drum 66.

In the dividing step, as depicted in FIG. 5A, the frame 43 is placed on the upper surface of the frame support table 68 moved to the reference position, and is fixed in situ by the clamps 70. As a result, the upper end of the expansion drum 66 makes contact with the expansion tape 41 located between the substrate 33 and the frame 43. Next, the support structure 64 is lowered by the lift mechanism 72, whereby the upper surface of the frame support table 68 is moved to the expansion position below the upper end of the expansion drum 66, as shown in FIG. 5B. As a result, the expansion drum 66 is raised in relation to the frame support table 68, and the expansion tape 41 is expanded in the manner of being pushed upward by the expansion drum 66. When the expansion tape 41 is thus expanded, external forces in directions for expanding the expansion tape 41 are exerted on the substrate 33. By this, the substrate 33 is divided with the modified layers 39 as starting points into a plurality of substrates 13, whereby the BAW devices 11 are completed.

Note that the present invention is not limited to the description of the embodiment above, and can be carried out with various modifications. For instance, while the modified layer forming step is carried out after the acoustic wave diffusion region forming step in the above embodiment, the acoustic wave diffusion region forming step may be carried out after the modified layer forming step. In addition, while the substrate 33 is divided by use of the expanding apparatus 62 in the dividing step in the above embodiment, the substrate 33 can also be divided, for example, by use of a method in which the substrate 33 is pressed by pressing blades along the division lines 35.

The present invention is not limited to the details of the above described preferred embodiment. The scope of the invention is defined by the appended claims and all changes and modifications as fall within the equivalence of the scope of the claims are therefore to be embraced by the invention.

What is claimed is:

1. A bulk acoustic wave device comprising:
a substrate;
a piezoelectric element formed on a front surface of the substrate;
the substrate being provided on a back surface side thereof with an acoustic wave diffusion region including a recess formed by partially melting a back surface of the substrate.

2. A bulk acoustic wave device manufacturing method for manufacturing a bulk acoustic wave device, the bulk acoustic wave device including
a substrate,
a piezoelectric element formed on a front surface of the substrate,
the substrate being provided on a back surface side thereof with an acoustic wave diffusion region including a recess formed by partially melting a back surface of the substrate, the bulk acoustic wave device manufacturing method comprising:
a substrate preparation step of preparing the substrate formed on the front surface thereof with the piezoelectric element; and
an acoustic wave diffusion region forming step of applying a laser beam having such a wavelength as to be absorbed in the substrate from the back surface side of the substrate, to partially melt the back surface of the substrate, thereby forming an acoustic wave diffusion region including a recess.
